(19) United States
(12) Patent Application Publication
(10) Pub. No.: US 2015/0187841 A1
(43) Pub. Date: Jul. 2, 2015

(54) Method of forming current-programmable inline resistor

(71) Applicant: Intermolecular Inc., San Jose, CA (US)

(72) Inventors: Yun Wang, San Jose, CA (US); Mihir Tendulkar, Mountain View, CA (US); Milind Weling, Pleasanton, CA (US)

(73) Assignee: Intermolecular Inc., San Jose, CA (US)

(21) Appl. No.: 14/140,723

(22) Filed: Dec. 26, 2013

(51) Int. Cl. H01L 27/24; H01L 49/02; H01L 45/00

(52) U.S. Cl. CPC H01L 27/2463; H01L 45/146; H01L 45/1641; H01L 28/24; H01L 45/1233

(57) ABSTRACT

Provided are resistive random access memory (ReRAM) cells and methods of fabricating thereof. A ReRAM cell includes an embedded resistor and a variable resistance layer that are interconnected in series by, for example, stacking the two. The embedded resistor prevents excessive electrical currents through the variable resistance layer thereby preventing its over-programming. The embedded resistor is configured to maintain a constant resistance during the operation of the ReRAM cell, such as applying switching currents and changing the resistance of the variable resistance layer. Specifically, the embedded resistor may be electrically broken down during fabrication of the ReRAM cell to improve the subsequent stability of the embedded resistance to electrical fields during operation of the ReRAM cell. The embedded resistor may be made from materials that allow this initial breakdown and to avoid future breakdowns, such metal silicon nitrides, metal aluminum nitrides, and metal boron nitrides.

### BACKGROUND

Nonvolatile memory is computer memory capable of retaining stored information even when unpowered. Non-volatile memory is typically used for secondary storage or long-term persistent storage and may be used in addition to volatile memory, which loses the stored information when unpowered. Nonvolatile memory can be permanently integrated into computer systems (e.g., solid state hard drives) or can take the form of removable and easily transportable memory cards (e.g., USB flash drives). Nonvolatile memory is becoming more popular because of its small size/high density, low power consumption, fast read and write rates, retention, and other characteristics.

Flash memory is a common type of nonvolatile memory because of its high density and low fabrication costs. Flash memory is a transistor-based memory device that uses multiple gates per transistor and quantum tunneling for storing the information on its memory device. Flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. For example, nonvolatile memory is expected to replace hard drives in many new computer systems. However, transistor-based flash memory is often inadequate to meet the requirements for nonvolatile memory. New types of memory, such as resistive random access memory, are being developed to meet these demands and requirements.

### SUMMARY

Provided are resistive random access memory (ReRAM) cells and methods of fabricating thereof. A ReRAM cell includes an embedded resistor and a variable resistance layer that are interconnected in series by, for example, stacking the two. The embedded resistor prevents excessive electrical currents through the variable resistance layer thereby preventing its over-programming. The embedded resistor is configured to maintain a constant resistance during the operation of the ReRAM cell, such as applying switching currents and changing the resistance of the variable resistance layer. Specifically, the embedded resistor may be electrically broken down during fabrication of the ReRAM cell to improve the subsequent stability of the embedded resistance to electrical fields during operation of the ReRAM cell. The embedded resistor may be made from materials that allow this initial breakdown and to avoid future breakdowns, such metal silicon nitrides, metal aluminum nitrides, and metal boron nitrides.

In some embodiments, a ReRAM cell includes a first signal line, a second signal line, a variable resistance layer disposed between the first signal line and the second signal line, and an embedded resistor disposed between the first signal line and the second signal line. The embedded resistor includes one of a metal silicon nitride, a metal aluminum nitride, or a metal boron nitride. The embedded resistor is interconnected in series with the variable resistance layer in between first signal line and the second signal line. The embedded resistor is an electrically broken down dielectric having a lower resistance in comparison to a dielectric having the same composition prior to an electrical breakdown. In other words, the embedded resistor has been electrically broken down during fabrication of the ReRAM cell, which resulted in the resistance drop of the embedded resistor during this electrical breakdown.

In some embodiments, the embedded resistor includes one of tantalum silicon nitride, tantalum aluminum nitride, tantalum boron nitride, titanium silicon nitride, titanium aluminum nitride, titanium boron nitride, tungsten silicon nitride, tungsten aluminum nitride, tungsten boron nitride, molybdenum silicon nitride, molybdenum aluminum nitride, or molybdenum boron nitride. More specifically, the embedded resistor includes tantalum silicon nitride. In some embodiments, an atomic ratio of tantalum to silicon in the embedded resistor is between 2 and 20. The concentration of nitrogen in the embedded resistor may be between 20% atomic and 60% atomic. The embedded resistor may have a thickness of between about 5 nanometers and 50 nanometers. In some embodiments, the variable resistance layer includes hafnium oxide. The ReRAM cell may also include an interface layer disposed between the variable resistance layer and the embedded resistor. The interface layer may include a metal.

In some embodiments, a method of fabricating a ReRAM cell involves providing a substrate and forming an embedded resistor on the substrate. The embedded resistor may include one of a metal silicon nitride, a metal aluminum nitride, or a metal boron nitride. The method may proceed with forming a variable resistance layer on the embedded resistor such that the variable resistance layer and the embedded resistor form a stack in which the variable resistance layer and the embedded resistor are interconnected in series. The method may proceed with passing a first current through the stack such that passing the first current causes an electrical breakdown within the embedded resistor and reduces the resistance of the embedded resistor.

In some embodiments, passing the first current changes the resistance of the resistance of the variable resistance. For example, passing the first current may reduce the resistance of the resistance of the variable resistance. In some embodiments, the method also involves passing a second current through the stack. The second current may change the resistance of the variable resistance layer while the resistance of the embedded resistor remains substantially the same while passing the second current. The first current and the second current may be passed in the same direction through the stack. In some embodiments, the second current reduces the resistance of the variable resistance layer. The method may also involve passing a third current through the stack. The third current increases the resistance of the variable resistance layer, while the resistance of the embedded resistor remains substantially the same while passing the third current. In some embodiments, the second current and the third current are passed in opposite directions through the stack.

In some embodiments, passing the first current involves applying a voltage of between 2 Volts and 12 Volts to the stack. After passing the first current, a ratio of the resistance of the variable resistance layer and the resistance of the embedded resistor may be between about 0.25 and 4. The resistivity the embedded resistor may be between 0.1 Ohm-cm and 5 Ohm-cm after passing the first current. In some embodiments, the resistance of the embedded resistor reduces by more than 100 times while passing the first current.

Provided also is a method that involves providing a ReRAM cell including a variable resistance layer and an embedded resistor. The variable resistance layer includes hafnium oxide. The embedded resistor includes tantalum silicon nitride and has a thickness of between 5 nanometers and 50 nanometers. The variable resistance layer and the embedded resistor are interconnected in series. The method proceeds with passing a breakdown current through the variable resistance layer and the embedded resistor. This passing of the breakdown current variable resistance reduces a resistance of the embedded resistor. In some embodiments, the breakdown current also reduces a resistance of the resistive-switching layer. After passing the breakdown current, the method proceeds with passing a switching current through the variable resistance layer and the embedded resistor. This passing of the switching current changes the resistance of the variable resistance layer, while the resistance of the embedded resistor remains substantially the same.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings, in which:

FIGS. 1A illustrate schematic representations of a ReRAM cell prior to initial forming operation, in accordance with some embodiments.

FIGS. 1B and and 1C illustrate schematic representations of the ReRAM cell in its high resistive state (HRS) and low resistive state (LRS), in accordance with some embodiments.

FIG. 2A illustrates a plot of a current passing through a unipolar ReRAM cell as a function of a voltage applied to the ReRAM cell, in accordance with some embodiments.

FIG. 2B illustrates a plot of a current passing through a bipolar ReRAM cell as a function of a voltage applied to the ReRAM cell, in accordance with some embodiments.

FIG. 3 illustrates a schematic representation of a ReRAM cell including an embedded resistor, variable resistance layer, and other components, in accordance with some embodiments.

FIG. 4 illustrates a process flowchart corresponding to a method of fabricating a ReRAM cell, in accordance with some embodiments.

FIGS. 5A and 5B illustrate schematic views of memory arrays including multiple ReRAM cells, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

A ReRAM cell exhibiting variable resistance characteristics generally includes multiple layers formed into a stack, such as a “metal-insulator-metal” (MIM) stack. The stack includes two conductive layers operating as electrodes, which are identified as “M” and may include a metal, but may also include other types of conductive materials, such as doped silicon. The stack also includes an insulator layer provided in between the two electrodes and identified as “I”. The insulator layer changes its resistive properties when certain switching voltages are applied to the layer or, more generally, to the ReRAM cell including this layer. Due to its variable resistance characteristics, the insulator layer may be also referred to as a variable resistance layer. These changes in resistive properties are used to store data. For example, when two different resistive states are identified (e.g., a high resistive state and a low resistive state) for a ReRAM cell, one state may be associated with a logic “zero”, while the other state may be associated with a logic “one” value. Similar approaches may be used when three or more resistive states may be identified for the same ReRAM cell leading to various multibit architectures.

The switching voltages may be applied as series of pulses and may be generally referred to as switching voltage profiles or, more specifically, set voltage profiles and reset voltage profiles. For example, a switching voltage pulse may be used to change (“set” or “reset”) the resistive state followed by a smaller reading voltage pulse to determine the current state of the ReRAM cell at that time. Unlike the switching voltage pulse, the reading pulse is specifically configured to avoid changing the resistive state of the ReRAM cell and is configured only to determine the current state. The switching pulse may be repeated if the desired resistive state is not reached. The switching pulses may alternate with the reading pulses for feedback control. The switching pulses may vary from one to another based on their potential (e.g., a gradual increase in the potential), duration, and other characteristics. The reading pulses may be the same. The process of applying the switching pulses and reading pulses may continue until the desired resistive state is reached.

The change in resistance of the variable resistance layer is a dynamic process that needs to be well controlled to prevent over-programming. For example, when the variable resistance layer is switched from its high resistive state (HRS) to its low resistive state (LRS), a rapid drop in resistance associated with this switch may cause an excessive current through the variable resistance layer and an over-programming. The over-programming occurs when change in the resistance continues even after the variable resistance layer reaches its desirable resistance. One approach to prevent over-programming is by using very short pulses, e.g., about 50 nanoseconds, followed by a reading pulse. If the desired resistive state is not reached, another pulse is applied. The process of applying switching and reading pulses may be repeated until the desired resistance is not reached. However, shorter pulses have their own inherent limitations, such as requiring more pulses or higher voltages to achieve the same switching result, which may consume more power than fewer, longer, lower-voltage pulses. Furthermore, even during a relatively short switching pulse, the change in resistance may be sufficiently large to result in current spiking and over-programming. In some embodiments, the difference in resistances between the LRS and the HRS may be more than an order of magnitude to allow the read pulses to easily differentiate between the two states.

To prevent current spiking and over-programming, an embedded resistor is connected in series with the variable resistance layer and is used to limit the current through the variable resistance layer. The embedded resistor effectively functions as a voltage divider within the ReRAM cell. Unlike the variable resistance layer, the embedded resistor maintains a constant resistance throughout the entire operation of the cell. As a relative change of the overall ReRAM cell resistance (expressed as a ratio of the change in the resistance of the ReRAM cell to the overall initial resistance) when the variable resistance layer goes between the LRS and the HRS is less for ReRAM cells with embedded resistors than for similar cells without embedded resistor. This voltage divider/constant resistance characteristic of the embedded resistor helps to prevent the current spiking and over-programming.

Embedded resistors are subjected to a few design and fabrication constraints. First, the thickness of embedded resistors may be between about 1 nanometer to about 50 nanometers or, more specifically, between 2 nanometers to about 10 nanometers. In order to achieve an adequate voltage drop, the resistivity of the material forming the embedded resistor has to be between about 0.1-40 Ohm-cm or, more specifically, 1-4 Ohm-cm. Furthermore, these thickness values place significant constraints on fabrication options and even materials selections. Not that many materials can be formed into such thin layers and achieved the desired resistivity as well thermal and electrical stability characteristics. For example, diode activation subjects the entire ReRAM cell including its embedded resistor to a temperature of up to 750° C. or more for up to about 1 minute or more. Furthermore, during operation of the ReRAM cell, the embedded may be subjected to strong electrical fields, e.g., up to 12 mega-Volts/centimeter.

The embedded resistor material should not exhibit any significant loss in its resistivity or compromise the remaining materials in the stack by, for example, displacing some of its components into adjacent layers. The change in resistivity after being subject to the diode activation should be less than an order of magnitude. Furthermore, the change in resistivity when subjected to the electrical fields during operation of the cells should be minimal if any.

Not many materials are capable of withstanding these strict design requirements as well as operating requirements. For example, many materials are susceptible to electrical breakdowns when subjected to electrical fields commonly used in ReRAM cells. An electrical breakdown causes the material to reduce its initial resistivity, often by more than a factor of 100. Therefore, if an embedded resistor, which is designed to provide a specific resistance in a ReRAM cell, is later broken down during operation, the entire cell may be destroyed.

It has been found that once a material is electrically broken down, it is less susceptible to future breakdowns. As such, a material may be purposely broken down during fabrication of a ReRAM cell to prevent future breakdowns during operation of this cell. Specifically, an embedded resistor may initially formed and then electrically broken down prior to operating the ReRAM cell. After its breakdown, the embedded resistor needs to have a resistance suitable for operation of the ReRAM cell. For example, the resistance of the embedded resistor (at this stage) may be comparable to the resistance of the variable resistance layer of the same cell. Overall, the electrical breakdown needs to be performed in a controlled manner to achieve this desired resistance. Furthermore, the embedded resistor needs to be made from materials that would allow this initial breakdown to proceed in a controllable manner and yield an embedded resistor with suitable characteristics post-breakdown. Other factors that can impact the breakdown process include the morphology of the materials forming the embedded resistor as well the geometry and size of the embedded resistor.

Examples of Nonvolatile ReRAM Cells and their Switching Mechanisms

A brief description of ReRAM cells is provided for context and better understanding of various features associated with embedded resistors in the ReRAM cells. As stated above, a ReRAM cell includes a dielectric material formed into a layer exhibiting variable resistance characteristics. A dielectric, which is normally insulating, can be made to conduct through one or more conductive paths formed after application of a voltage. The conductive path formation can arise from different mechanisms, including defects, metal migration, and other mechanisms further described below. Once one or more conductive paths (e.g., filaments) are formed in the dielectric component of a memory device, these conductive paths may be reset (or broken resulting in a high resistance) or set (or re-formed resulting in a lower resistance) by applying certain voltages. Without being restricted to any particular theory, it is believed that variable resistance corresponds to migration of defects within the variable resistance layer and, in some embodiments, across one interface formed by the variable resistance voltage, when a switching voltage is applied to the layer.

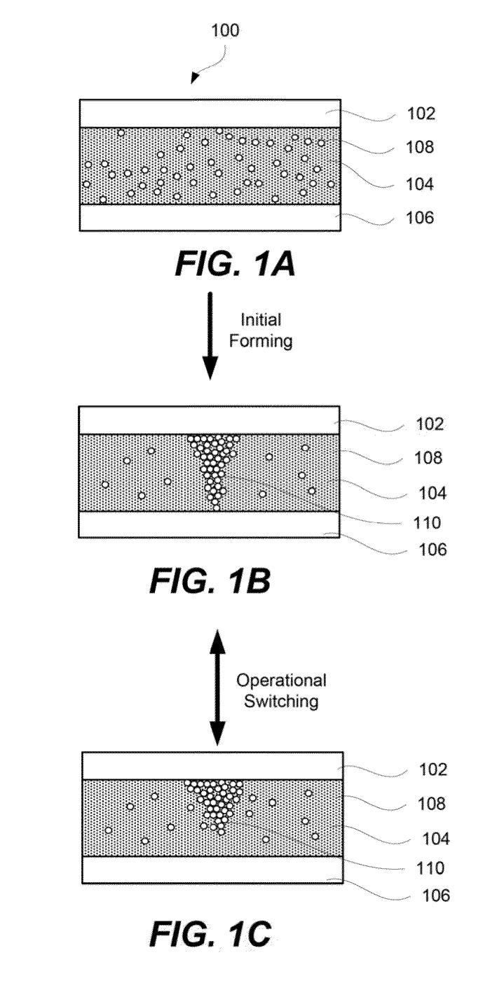

FIG. 1A illustrates a schematic representation of ReRAM cell 100 including first electrode 102, second electrode 106, and variable resistance layer 104 disposed in between first electrode 102 and second electrode 106. It should be noted that the “first” and “second” references for electrodes 102 and 106 are used solely for differentiation and not to imply any processing order or particular spatial orientation of these electrodes. ReRAM cell 100 may also include other components, such as an embedded resistor, diode, diffusion barrier layer, and other components. ReRAM cell 100 is sometimes referred to as a memory element or a memory unit.

First electrode 102 and second electrode 106 may be used as conductive lines within a memory array or other types of devices that ReRAM cell is integrated into. As such, electrode 102 and 106 are generally formed from conductive materials. As stated above, one of the electrodes may be reactive electrode and act as a source and as a reservoir of defects for the variable resistance layer. That is, defects may travel through an interface formed by this electrode with the variable resistance layer (i.e., the reactive interface).

Variable resistance layer 104 which may be initially formed from a dielectric material and later can be made to conduct through one or more conductive paths formed within the layer by applying first a forming voltage and then a switching voltage. To provide this variable resistance functionality, variable resistance layer 104 includes a concentration of electrically active defects 108, which may be at least partially provided into the layer during its fabrication. For example, some atoms may be absent from their native structures (i.e., creating vacancies) and/or additional atoms may be inserted into the native structures (i.e., creating interstitial defects). Charge carriers may be also introduced as dopants, stressing lattices, and other techniques. Regardless of the types all charge carriers are referred to as defects 108.

FIG. 1A is a schematic representation of ReRAM cell 100 prior to initial formation of conductive paths, in accordance with some embodiments. Variable resistance layer 104 may include some defects 108. Additional defects 108 may be provided within first electrode 102 and may be later transferred to variable resistance layer 104 during the formation operation. In some embodiments, the variable resistance layer 104 has substantially no defects prior to forming operation and all defects are provided from first electrode 102 during forming. Second electrode 106 may or may not have any defects. It should be noted that regardless of presence or absence of defects in second electrode 106, substantially no defects are exchanged between second electrode 106 and variable resistance layer 104 during forming and/or switching operations.

During the forming operation, ReRAM cell 100 changes its structure from the one shown in FIG. 1A to the one shown in FIG. 1B. This change corresponds to defects 108 being arranged into one or more continuous paths within variable resistance layer 104 as, for example, schematically illustrated in FIG. 1B. Without being restricted to any particular theory, it is believed that defects 108 can be relocated or reoriented within variable resistance layer 104 to form these conductive paths as, for example, schematically shown in FIG. 1B. Furthermore, some or all defects 108 forming the conductive paths may enter variable resistance layer 104 from first electrode 102. For simplicity, all these phenomena are collectively referred to as reorientation of defects within ReRAM cell 100. This reorientation of defects 108 occurs when a certain forming voltage is applied to electrodes 102 and 106. In some embodiments, the forming operation also conducted at elevated temperatures to enhanced mobility of the defects within ReRAM cell 100. In general, the forming operation is considered to be a part of the fabrication of ReRAM cell 100, while subsequent variable resistance is considered to be a part of operation of ReRAM cell.

Variable resistance involves breaking and reforming conductive paths through variable resistance layer 104, i.e., switching between the state schematically illustrated in FIG. 1B and the state schematically illustrated in FIG. 1C. The variable resistance is performed by applying switching voltages to electrodes 102 and 106. Depending on the magnitude and polarity of these voltages, conductive path 110 may be broken or restored. These voltages may be substantially lower than forming voltages (i.e., voltages used in the forming operation) since much less mobility of defects is needed during switching operations. For example, hafnium oxide based resistive layers may need about 7 Volts during their forming but can be switched using voltages less than 4 Volts.

The state of variable resistance layer 104 illustrated in FIG. 1B is referred to as a low resistance state (LRS), while the state illustrated in FIG. 1C is referred to as a high resistance state (HRS). The resistance difference between the LRS and HRS is due to the different number and/or conductivity of conductive paths that exists in these states, i.e., variable resistance layer 104 has more conductive paths and/or less resistive conductive paths when it is in the LRS than when it is in the HRS. It should be noted that variable resistance layer 104 may still have some conductive paths while it is in the HRS, but these conductive paths are fewer and/or more resistive than the ones corresponding to the LRS.

When switching from its LRS to HRS, which is often referred to as a reset operation, variable resistance layer 104 may release some defects into first electrode 102. Furthermore, there may be some mobility of defects within variable resistance layer 104. This may lead to thinning and, in some embodiments, breakages of conductive paths as shown in FIG. 1C. Depending on mobility within variable resistance layer 104 and diffusion through the interface formed by variable resistance layer 104 and first electrode 102, the conductive paths may break closer to the interface with second electrode 106, somewhere within variable resistance layer 104, or at the interface with first electrode 102. This breakage generally does not correspond to complete dispersion of defects forming these conductive paths and may be a self-limiting process, i.e., the process may stop after some initial breakage occurs.

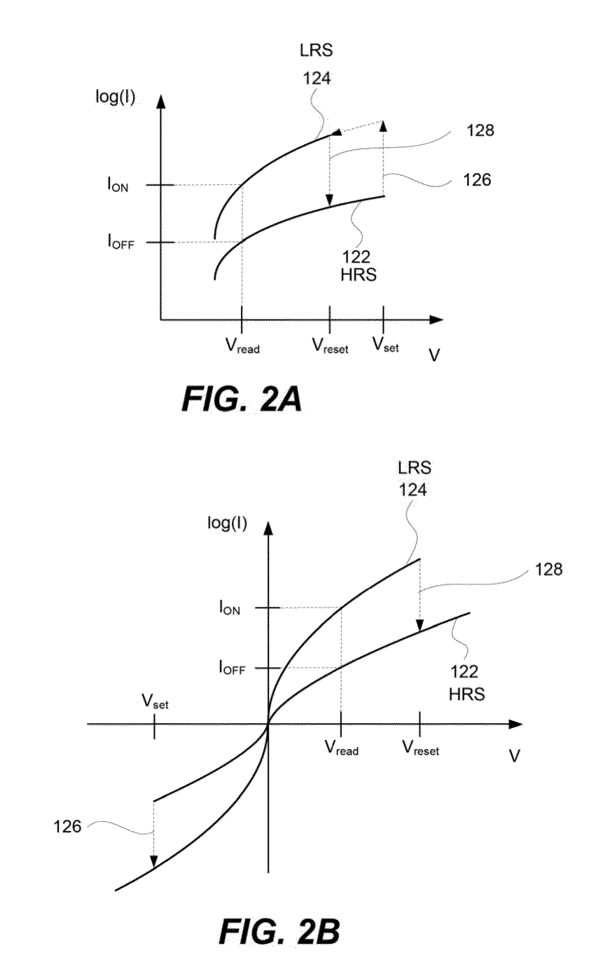

When switching from its HRS to LRS, which is often referred to as a set operation, variable resistance layer 104 may receive some defects from first electrode 102. Similar to the reset operation described above, there may be some mobility of defects within variable resistance layer 104. This may lead to thickening and, in some embodiments, reforming of conductive paths as shown in FIG. 1B. In some embodiments, a voltage applied to electrodes 102 and 106 during the set operation has the same polarity as a voltage applied during the reset operation. This type of switching is referred to as unipolar switching. Alternatively, a voltage applied to electrodes 102 and 106 during the set operation may have different polarity as a voltage applied during the reset operation. This type of switching is referred to as bipolar switching. Setting and resetting operations may be repeated multiple times as will now be described with reference to FIGS. 2A and 2B.

Specifically, FIG. 2A illustrates a plot of a current passing through a unipolar ReRAM cell as a function of a voltage applied to the ReRAM cell, in accordance with some embodiments. FIG. 2B illustrates the same type of a plot for a bipolar ReRAM cell, in accordance with some embodiments. The HRS is defined by line 122, while the LRS is defined by 124 in both plots. Each of these states is used to represent a different logic state, e.g., the HRS may represent logic one (“1”) and LRS representing logic zero (“0”) or vice versa. Therefore, each ReRAM cell that has two resistance states may be used to store one bit of data. It should be noted that some ReRAM cells may have three and even more resistance states allowing multi-bit storage in the same cell.

The overall operation of the ReRAM cell may be divided into a read operation, a set operation (i.e., turning the cell “ON” by changing from its HRS to LRS), and a reset operation (i.e., turning the cell “OFF” by changing from its LRS to HRS). During the read operation, the state of the ReRAM cell or, more specifically, the resistive state of its resistance of variable resistance layer can be sensed by applying a sensing voltage to its electrodes. The sensing voltage is sometimes referred to as a “READ” voltage or simply a reading voltage and indicated as V_{READ} in FIG. 2. If the ReRAM cell is in its HRS (represented by line 122 in FIGS. 2A and 2B), the external read and write circuitry connected to the electrodes will sense the resulting “OFF” current (I_{OFF}) that flows through the ReRAM cell. As stated above, this read operation may be performed multiple times without changing the resistive state (i.e., switching the cell between its HRS and LRS). In the above example, the ReRAM cell should continue to output the “OFF” current (I_{OFF}) when the read voltage (V_{READ}) is applied to the electrodes for the second time, third time, and so on.

Continuing with the above example, when it is desired to turn “ON” the cell that is currently in the HRS, a set operation is performed. This operation may use the same read and write circuitry to apply a set voltage (V_{SET}) to the electrodes. Applying the set voltage forms one or more conductive paths in the variable resistance layer as described above with reference to FIGS. 1B and 1C. The switching from the HRS to the LRS is indicated by dashed line 126 in FIGS. 2A and 2B. The resistance characteristics of the ReRAM cell in its LRS are represented by line 124. When the read voltage (V_{READ}) is applied to the electrodes of the cell in this state, the external read and write circuitry will sense the resulting “ON” current (I_{ON}) that flows through the ReRAM cell. Again, this read operation may be performed multiple times without switching the state of the ReRAM cell.

At some point, it may be desirable to turn “OFF” the ReRAM cell by changing its state from the LRS to HRS. This operation is referred to as a reset operation and should be distinguished from set operation during which the ReRAM cell is switched from its HRS to its LRS. During the reset operation, a reset voltage (V_{RESET}) is applied to the ReRAM cell to break the previously formed conductive paths in the variable resistance layer. Switching from LRS to HRS is indicated by dashed line 128. Detecting the state of the ReRAM cell while it is in its HRS is described above.

Overall, the ReRAM cell may be switched back and forth between its LRS and HRS many times. Read operations may be performed in each of these states (between the switching operations) one or more times or not performed at all. It should be noted that application of set and reset voltages to change resistance states of the ReRAM cell involves complex mechanisms that are believed to possibly involve localized resistive heating as well as mobility of defects impacted by both temperature and applied potential.

In some embodiments, the set voltage (V_{SET}) is between about 100 mV and 10V or, more specifically, between about 500 mV and 5V. The length of set voltage pulses (t_{SET}) may be less than about 100 milliseconds or, more specifically, less than about 5 milliseconds and even less than about 100 nanoseconds. The read voltage (V_{READ}) may be between about 0.1 and 0.5 of the write voltage (V_{SET}). In some embodiments, the read currents (I_{ON} and I_{OFF}) are greater than about 1 mA or, more specifically, is greater than about 5 mA to allow for a fast detection of the state by reasonably small sense amplifiers. The length of read voltage pulse (t_{READ}) may be comparable to the length of the corresponding set voltage pulse (t_{SET}) or may be shorter than the write voltage pulse (t_{RESET}). ReRAM cells should be able to cycle between LRS and HRS between at least about 10³ times or, more specifically, at least about 10⁷ times without failure. A data retention time (t_{RET}) should be at least about 5 years or, more specifically, at least about 10 years at a thermal stress up to 85° C. and small electrical stress, such as a constant application of the read voltage (V_{READ}). Other considerations may include low current leakage, such as less than about 40 A/cm² measured at 0.5 V per 20 Å of oxide thickness in HRS.

### Examples of ReRAM Cells

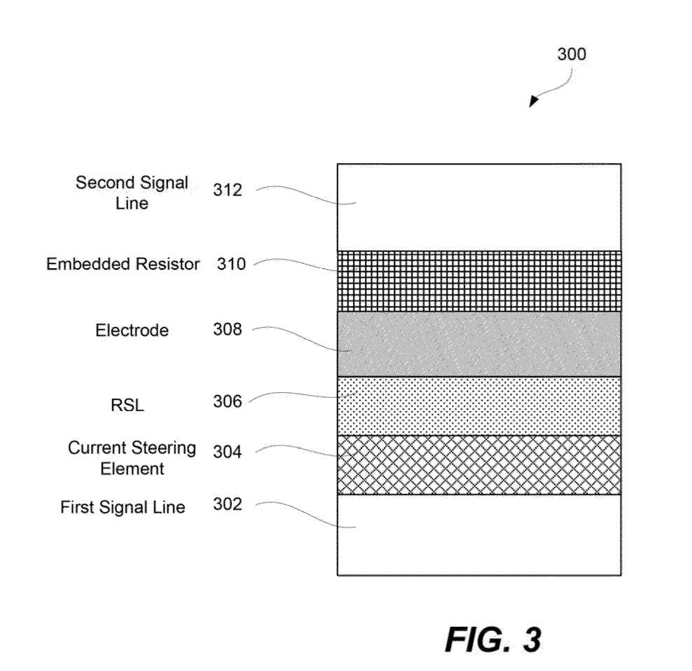

FIG. 3 illustrates a schematic representation of a ReRAM cell 300, in accordance with some embodiments. ReRAM cell 300 may include a first signal line 302, a current steering element 304, a variable resistance layer 306, an intermediate electrode 308, an embedded resistor 310, and a second signal line 312. The “first” and “second” terminology is used herein only for differentiating reasons and does not imply any deposition order or spatial orientation of the layers unless specifically noted. In some embodiments, ReRAM cell 300 has more or fewer layers. For example, an intermediate layer may be disposed between electrode 308 and embedded resistor 310 in order to improve electrical connection between electrode 308 and embedded resistor 310. Furthermore, current steering element 304 and/or intermediate electrode 308 may be omitted from ReRAM cell 300. In some embodiments, embedded resistor 310 may directly interface variable resistance layer 306.

In the example illustrated in FIG. 3, a portion of current steering element 304 is also operable as another intermediate electrode interfacing variable resistance layer 306. Likewise, when intermediate electrode 308 is not present, a portion of embedded resistor 310 may be operable as an intermediate electrode. In some embodiments, variable resistance layer 306 is positioned in between and directly interfaces two designated electrodes. Regardless of these configurations, one electrode (standalone or a part of another component) interfacing variable resistance layer 306 may be an inert electrode and may not exchange defects with variable resistance layer 306. Another electrode (standalone or a part of another component) that also interfaces variable resistance layer 306 may be active and may exchange defects with variable resistance layer 306. For example, a titanium nitride electrode may accept and release oxygen vacancies into variable resistance layer 306, while a doped polysilicon electrode may form a passivation silicon oxide layer that blocks defects from going in and out of variable resistance layer 306. In the example illustrated in FIG. 3, current steering element 304 may include a bottom p-doped polysilicon portion, which interfaces second signal line 312, a top n-doped polysilicon portion, which interfaces variable resistance layer 306 and is operable as an electrode, more specifically, an inert electrode.

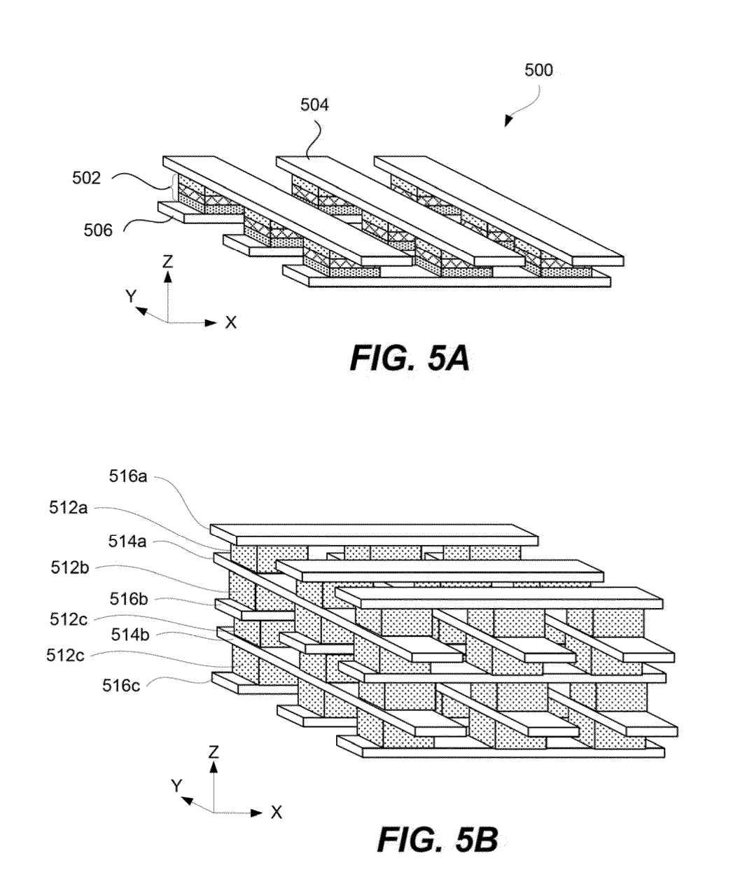

In some embodiments, the electrodes may be sufficiently conductive and may be used as signal lines. Alternatively, signal lines and electrodes may be separate components as, for example, illustrated in FIG. 3. First signal line 302 and second signal line 312 provide electrical connections to ReRAM cell 300. For example, first signal line 302 and/or second signal line 312 may extend between multiple ReRAM cells, which may be cells connected in the same row or the same column of a memory array as further described below with reference to FIGS. 5A and 5B. First signal line 302 and second signal line 312 may be made from conductive materials, such as n-doped polysilicon, p-doped polysilicon, titanium nitride, ruthenium, iridium, platinum, and tantalum nitride. The signal lines may have a thickness of less than about 100 nanometers, such as less than about 50 nanometers and even less than about 10 nanometers. Thinner electrodes may be formed using atomic layer deposition (ALD) techniques.

Current steering element 304, if one is present, may be an intervening electrical component, such as a p-n junction diode, p-i-n diode, transistor, or other similar device disposed between first signal line 302 and second signal line 312. As such, current steering element 304 is connected in series with variable resistance layer 306. In some embodiments, current steering element 304 may include two or more layers of semiconductor materials, such as two or more doped silicon layers, that are configured to direct the flow of current through the device. Current steering element 304 may be a diode that includes a p-doped silicon layer, an un-doped intrinsic layer, and an n-doped silicon layer. These layers are not specifically identified in FIG. 3. The overall resistance of current steering element 304 may be between about 1 kilo-Ohm and about 100 Mega-Ohm. The overall resistance generally depends on the type of current steering element 304 and direction of the current flow through current steering element 304 (e.g., forward or reversed biased).

Variable resistance layer 306 can be fabricated from a dielectric material, such as a metal oxide material or other similar material that can be switched between two or more stable resistive states. In some embodiments, variable resistance layer 306 is fabricated from a high bandgap material, e.g., a material that has a bandgap of at least about 4 electron Volts. Some examples of such materials include hafnium oxide (HfₓO_{y}), tantalum oxide (TaₓO_{y}), aluminum oxide (AlₓO_{y}), lanthanum oxide (LaₓO_{y}), yttrium oxide (YₓO_{y}), dysprosium oxide (DyₓO_{y}), ytterbium oxide (YbₓO_{y}) and zirconium oxide (ZrₓO_{y}). The high bandgap materials may improve data retention in ReRAM cell 300 and reduce the current leakage since the amount of trapped charge in these materials is less than a lower bandgap material. Furthermore, the high bandgap materials create a large barrier height that the carriers have to cross during the read, set, and reset operations. Other suitable materials for variable resistance layer 306 include titanium oxide (TiOₓ), nickel oxide (NiOₓ), and cerium oxide (CeOₓ). Furthermore, semi-conductive metal oxide (p-type or n-type), such as zinc oxides (ZnₓO_{y}), copper oxides (CuₓO_{y}), and their nonstoichiometric and doped variants can be used for variable resistance layer 306.

In some embodiments, variable resistance layer 306 includes a dopant that has an affinity for oxygen, such as various transition metals (e.g., aluminum, titanium, and zirconium), to form a metal-rich variable resistance layer, such as a non-stoichiometric oxide (e.g., HfO_{1.5}—HfO_{1.9} or, more specifically, HfO_{1.7}). The dopant may be the same material as a metal of the base oxide (e.g., HfO₂ doped with hafnium) or different (e.g., HfO₂ doped with aluminum, titanium, and zirconium). Oxygen deficiency of the metal-rich variable resistance layer corresponds to a number of oxygen vacancies, which are believed to be defects responsible for variable resistance. The amount of defects is controlled to achieve certain switching and forming voltages, operating currents, improve performance consistency and data retention.

Variable resistance layer 306 may have a thickness of between about 1 nanometer to about 100 nanometers, such as between about 2 nanometers and 20 nanometers or, more specifically, between about 5 nanometers and 10 nanometers. Thinner variable resistance layers may be deposited using ALD, while thicker variable resistance layers may be deposited using may be deposited using ALD or physical vapor deposition (PVD) or, in some embodiments, chemical vapor deposition (CVD).

Electrode 308 may be fabricated from a conductive material that has a desirable conductivity and work function, such as p-type polysilicon, n-type polysilicon, transition metals, transition metal alloys, transition metal nitrides, or transition metal carbides. For example, electrode 308 may include one or more of titanium (Ti), tungsten (W), tantalum (Ta), cobalt (Co), molybdenum (Mo), nickel (Ni), vanadium (V), hafnium (Hf) aluminum (Al), copper (Cu), platinum (Pt), palladium (Pd), iridium (Ir), or ruthenium (Ru). Electrode 308 may include titanium/aluminum alloy and/or a silicon-doped aluminum. In some embodiments, electrode 308 may be formed from titanium, tantalum, or aluminum. Electrode 308 may be between about 5 nanometers and about 500 nanometers thick or, more specifically, between about 10 nanometers and about 100 nanometers thick.

Embedded resistor 310 may be fabricated from one of metal silicon nitrides, metal aluminum nitrides, or metal boron nitrides. Specific examples of materials suitable for embedded resistor 310 include tantalum silicon nitride, tantalum aluminum nitride, tantalum boron nitride, titanium silicon nitride, titanium aluminum nitride, titanium boron nitride, tungsten silicon nitride, tungsten aluminum nitride, tungsten boron nitride, molybdenum silicon nitride, molybdenum aluminum nitride, and molybdenum boron nitride. In some embodiments, the embedded resistor is formed from tantalum silicon nitride. The atomic ratio of tantalum to silicon in the embedded resistor may be between 2 and 20. Without being restricted to any particular theory, it is believed that tantalum silicon nitride can be tuned for initial electrical breakdown to yield am embedded resistor with desirable characteristics.

Incorporation of silicon, aluminum, boron and/or nitrogen into embedded resistor 310 tends to increase its resistivity, while the base metal (e.g., tantalum, titanium, tungsten, molybdenum) helps to maintain its stable resistivity and high breakdown voltage characteristics especially after the initial breakdown. Furthermore, these metal silicon nitrides, metal aluminum nitrides, and metal boron nitrides tend to be stable when subjected to processing temperatures, such as at least about 750° C. for 60 seconds used for diode activation. In some embodiments, embedded resistor 310 retains its characteristics when subjected to a temperature of between about 500° C. to 1000° C. for about 10 seconds to 10 minutes, which may be used, for example, to activate diodes provided on the same substrate. Addition of silicon, aluminum, and/or boron into metal nitrides improves their thermal stability and helps to withstand crystallization (and remaining in their amorphous states).

As noted above, certain materials may be difficult to form into thin layers, while other materials can be formed into layers of essentially any thickness. In some embodiments, embedded resistor 310 has a thickness of between about 1 nanometer and 50 nanometers or, more specifically, between about 2 nanometers and 10 nanometers thick. The footprint (i.e., cross-sectional area) of embedded resistor 310 may be between about 20 nanometers-square and 100 nanometers-square or, more specifically, between about 30 nanometers-square and 60 nanometers-square, such as about 60 nanometers-square.

Once subjected to the initial breakdown, embedded resistor 310 provides a substantially constant resistivity when a field of up to about 12 Mega-Volts per centimeter or, more specifically, up to about 8 Mega-Volts per centimeter is applied to embedded resistor 310. For purposes of this disclosure, the substantially constant resistivity is defined as a resistivity that changes by less than one order of magnitude (i.e., less than about 10 times). In some embodiments, the resistivity of the material forming embedded resistor 310 is between about 0.1 Ohm-centimeter to 40 Ohm-centimeter or, more specifically, between about 1 Ohm-centimeter to 4 Ohm-centimeter after the initial electrical breakdown. The resistivity may be tuned to device dimensions. For example, a resistivity of 1-4 ohm-cm corresponds to about 100 kOhm when a resistor is about 4 nanometers thick for a typical footprint of a ReRAM cell. If the device CD is smaller, the target resistivity should be changed corresponding to reach the same resistance.

When a material for embedded resistor 310 includes two or more base metals, these base metals may be distributed evenly or non-evenly throughout embedded resistor 310. For example, one base metal (e.g., hathium) may be concentrated near an interface between embedded resistor 310 and a neighboring layer. This metal may provide more beneficial interface properties, such as an ohmic contact. The other base metal (e.g., tantalum) may be concentrated away from the interfaces and may provide more beneficial bulk properties, such as high breakdown voltage and thermal stability. When two base metals are used their atomic ratio may be between about 0.1 and 10 or, more specifically, between about 0.5 and 5, such as about 1.

Atomic ratios of one or more base metals to aluminum, silicon, or boron in embedded resistor 310 may be between about 0.1 to 10 or, more specifically, between 0.5 and 5, such as about 1. The precise ratio is determined by the resistivity requirement. Additional base metal tends to reduce resistivity, while additional aluminum, silicon, or boron tends to increase resistivity as described above.

The concentration of nitrogen may be between 10 percent atomic and 80 percent atomic, or more specifically, between 20 percent atomic and 60 percent atomic. The aluminum nitride portion of the metal aluminum nitride tend to be more thermally stable than the base metal nitride, which may lose some nitrogen, which transfers into the aluminum nitride portion or other components of ReRAM cell 300 or leaves the cell completely.

### Processing Examples

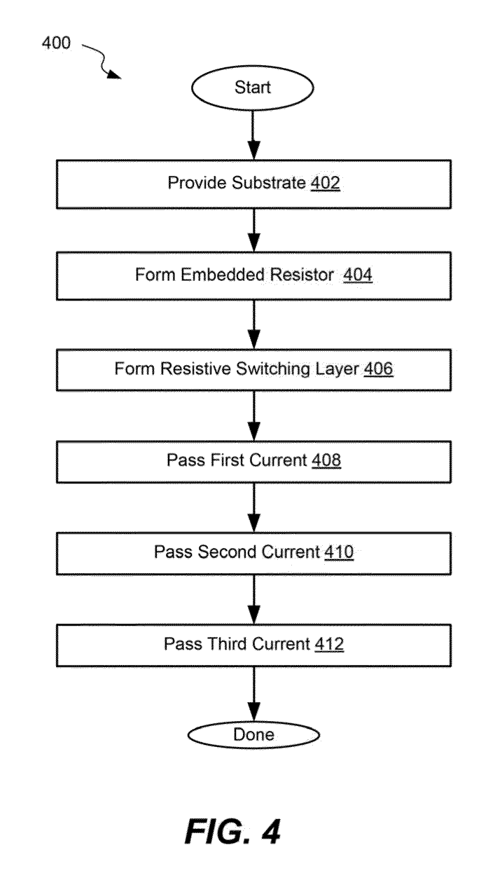

FIG. 4 illustrates a process flowchart corresponding to method 400 of fabricating a ReRAM cell, in accordance with some embodiments. Method 400 may commence with providing a substrate during operation 402. The substrate may include some components, such as a first signal line and a current steering element. In other embodiments, method 400 involves forming the first signal line and, for example, the current steering element on the substrate. The signal line can be made of silicon (e.g., doped polysilicon), a silicide, titanium nitride, or other appropriate materials listed elsewhere in this document. For example, a titanium nitride layer may be formed using PVD or other suitable deposition techniques. Deposition of the titanium nitride layer may be performed using a titanium target in a nitrogen atmosphere maintained at a pressure of between about 1-20 mTorr. The power may be maintained at 150-500 Watts with resulting in a deposition rate of about 0.05-0.5 nanometers per second. These process parameters are provided as examples and generally depend on deposited materials, tools, deposition rates, and other factors. Other processing techniques, such as ALD, PLD, CVD, evaporation, and the like can also be used to deposit the first signal line and, in some embodiments, the current steering element.

Method 400 may proceed with forming an embedded resistor during operation 404. Various examples of embedded resistors are described above with reference to FIG. 3. In some embodiments, the embedded resistor is formed from one of a metal silicon nitride, a metal aluminum nitride, or a metal boron nitride. Specific examples of materials suitable for the embedded resistor include tantalum silicon nitride, tantalum aluminum nitride, tantalum boron nitride, titanium silicon nitride, titanium aluminum nitride, titanium boron nitride, tungsten silicon nitride, tungsten aluminum nitride, tungsten boron nitride, molybdenum silicon nitride, molybdenum aluminum nitride, and molybdenum boron nitride. A ratio of each element in these materials may be specifically tailored to achieve desirable properties of the embedded resistor prior to its electrical breakdown and after its electrical breakdown.

Operation 404 may involve PVD, ALD, or other techniques. For example, tantalum aluminum nitride may be deposited using a PVD target including both tantalum and aluminum. Sputtering may be performed in a nitrogen-containing atmosphere. In this example, the composition of the embedded resistor depends on nitrogen concentration in the sputtering environment as well as relative amounts of tantalum and aluminum in the sputtering target. Likewise, titanium aluminum nitride may be deposited using a PVD target including a combination of titanium and aluminum in a nitrogen-containing atmosphere.

ALD may be also used to deposit an embedded resistor. Examples of silicon containing precursors that may be used for metal silicon nitride embedded resistors include (3-Aminopropyl) triethoxysilane (H₂N(CH₂)₃Si(OC₂H₅)₃), n-sec-Butyl(trimethylsilyl) amine (C₇H₁₉NSi), chloropentamethyldisilane ((CH₃)₃SiSi(CH₃)₂Cl), 1,2-dichlorotetramethyldisilane ([ClSi(CH₃)₂]₂), 1,3-diethyl-1,1,3,3-tetramethyldisilazane (C₈H₂₃NSi₂), 1,2-dimethyl-1,1,2,2-tetraphenyldisilane ((SiCH₃(C₆H₅)₂)₂), dodecamethylcyclohexasilane ((Si(CH₃)₂)₆), hexamethyldisilane ((Si(CH₃)₃)₂), hexamethyldisilazane, (CH₃)₃SiNHSi(CH₃)₃, methylsilane (CH₃SiH₃), 2,4,6,8,10-pentamethylcyclopentasiloxane ((CH₃SiHO)₅), pentamethyldisilane ((CH₃)₃SiSi(CH₃)₂H), silicon tetrabromide (SiBr₄), silicon tetrachloride (SiCl₄), tetraethylsilane (Si(C₂H₅)₄), 2,4,6,8-tetramethylcyclotetrasiloxane ((HSiCH₃O)₄), 1,1,2,2-Tetramethyldisilane ((CH₃)₂SiHSiH(CH₃)₂), tetramethylsilane (Si(CH₃)₄), n,n′,n″-tri-tert-butylsilanetriamine (HSi(HNC(CH₃)₃)3), tris(tert-butoxy)silanol (((CH3)3CO)3SiOH), and tris(tert-pentoxy)silanol ((CH₃CH₂C(CH₃)₂O)₃SiOH). Some examples of aluminum containing precursors for metal aluminum nitride embedded resistors include aluminum tris (2,2,6,6-tetramethyl-3,5-heptanedionate) (Al(OCC(CH3)₃CHCOC(CH₃)₃)₃), triisobutyl aluminum ([(CH₃)₂CHCH₂]₃Al), trimethyl aluminum ((CH₃)₃Al)—also known as TMA, Tris (dimethyl amido) aluminum (Al(N(CH₃)₂)₃). Examples of boron containing precursors for metal boron nitride embedded resistors include triisopropyl borate ([(CH₃)₂CHO]₃B), trimethylboron (B(CH₃)₃), and triphenylborane ((C₆H₅)₃B). The nitrogen containing oxidizing agent may include ammonia (NH3), which in some embodiments may be mixed with carbon monoxide (CO). Examples of hafnium containing precursors include bis(tert-butylcyclopentadienyl) dimethyl hafnium (C₂₀H₃₂Hf), bis (methyl-η5-cyclopentadienyl) methoxymethyl hafnium (HfCH₃(OCH₃)[C₅H₄(CH₃)]₂), bis(trimethylsilyl) amido hafnium chloride ([[(CH₃)₃Si]₂N]₂HfCl₂), dimethylbis(cyclopentadienyl) hafnium ((C₅H₅)₂Hf(CH₃)₂), hafnium isopropoxide isopropanol adduct (C₂₂H₂₈HfO₄), tetrakis(diethylamido) hafnium ([(CH₂CH₃)₂N]₄Hf)—also known as TEMAH, tetrakis(ethylmethylamido) hafnium ([(CH₃)(C₂H₅)N]₄Hf), tetrakis(dimethylamido) hafnium ([(CH₃)₂N]₄Hf)—also known as TDMAH, and hafnium tert-butoxide (HTB). Some hafnium containing precursors can be represented with a formula (RR′N) 4Hf, where R and R′ are independent hydrogen or alkyl groups and may be the same or different. Some example of tantalum containing precursors include pentakis (dimethylamino) tantalum (Ta(N(CH3)₂)₅), tris(diethylamido) (tert-butylimido) tantalum ((CH₃)₃CNTa(N(C₂H₅)₂)₃), tris(diethylamido) (ethylimido) tantalum (C₂H₅NTa(N(C₂H₅)₂)₃), tris(ethylmethylamido) (tert-butylimido) tantalum (C₁₃H₃₃N₄Ta). Examples of tungsten containing precursors include bis(butylcyclopentadienyl) tungsten diiodide (C₁₈H₂₆I₂W), bis(tert-butylimino)bis(tert-butylamino) tungsten ((C₄H₉NH)₂W(C₄H₉N)2), bis(tert-butylimino) bis(dimethylamino) tungsten (((CH₃)₃CN)2W(N(CH₃)₂)2), bis(cyclopentadienyl) tungstendichloride (C₁₀H₁₀Cl₂W), bis(cyclopentadienyl) tungsten dihydride (C₁₀H₁₂W), bis(isopropylcyclopentadienyl) tungsten dihydride ((C₅H₄CH(CH₃)₂)₂WH₂), cyclopentadienyl tungsten tricarbonyl hydride (C₈H₆O₃W), tetracarbonyl(1,5-cyclooctadiene)tungsten (C₁₂H₁₂O₄W), triamminetungsten tricarbonyl ((NH₃)₃W(CO)₃), tungsten hexacarbonyl (W(CO)₆).

The embedded resistor formed during operation 404 has a resistance much higher than the resistance desired eventually in an operational ReRAM cell. More specifically, its resistance after step 404 is higher than it will be after operation 408 further described below. Operation 408 is specifically configured to electrically break down the embedded resistor formed during operation 404. Operation 408 is typically performed when other components of the ReRAM cell, such as a variable resistance layer and a remaining signal line, are also formed.

Method 400 may proceed with forming a variable resistance layer during operation 406. The variable resistance layer may be formed directly over the embedded resistor. In some embodiments, the variable resistance layer is formed before the embedded resistor, e.g., directly over the first signal line or some other component. In this case, the embedded resistor is formed over the variable resistance layer. In other words, the order of operations 404 and 406 may be reversed. The embedded resistor may interface the variable resistance layer or may be separated by one or more other layers, e.g., an interface layer that prevents diffusion of materials between the embedded resistor and the variable resistance layer.

The variable resistance layer may be deposited using PVD or other suitable techniques. For example, a hafnium oxide layer having a thickness of between about 0.5-50 nanometers may be formed using reactive sputtering by employing a metal hafnium target in a 20-60% oxygen atmosphere. Power of 100-1000 Watts (W) may be used with a 5-7.5 cm diameter target to achieve deposition rates of between about 0.01 and 0.1 nanometers per second. These process parameters are provided as examples and generally depend on deposited materials, tools, deposition rates, and other factors. Other processing techniques, such as ALD, PLD, CVD, evaporation, and the like can also be used to deposit the variable resistance layer. For example, ALD can be used to form a hafnium oxide layer using hafnium precursors, such as tetrakis (diethylamido) hafnium (TDEAHf), tetrakis (dimethylamido) hafnium (TDMAHf), tetrakis (ethylmethylamido) hafnium (TEMAHf) or hafnium chloride (HfCl₄), and a suitable oxidant, such as water, oxygen plasma, or ozone.

A variable resistance layer may include multiple metals. For example, one metal may be used to dope an oxide of another metal. Two or more metals may be co-deposited to form one common layer or deposited in sequences to form multiple sub-layers of the variable resistance layer. For example, PVD may be used to deposit a layer containing hafnium oxide and aluminum oxide. Specifically, a co-sputtering arrangement using either a hafnium target and an aluminum target in an oxygen containing atmosphere or a hafnium oxide target and an aluminum oxide target may be used. In another example, ALD may be used to co-inject hafnium and aluminum precursors at desired proportions to co-deposit a metal oxide layer or to form multiple sub-layers. In some embodiments, operation 404 may involve ion implantation. The ion implantation can isovalently or aliovalently dope the variable resistance layer and can reduce forming voltages, improve set and reset voltage distributions, and increase device yield.

Method 400 may proceed with passing a first current through the stack during operation 408. Passing the first current may involve applying a voltage between signal lines of the ReRAM cell. Passing the first current causes an electrical breakdown within the embedded resistor and reduces a resistance of the embedded resistor. The reduced resistance of the embedded resistor remains after the first electrical current is discontinued. In other words, the electrical breakdown process is not reversible by any planned subsequent process in fabrication or operation of the ReRAM device. Furthermore, the embedded resistor becomes more stable and less prone to future possible electrical breakdowns after operation 408, for example, during operation of the ReRAM cell.

The breakdown mechanism that occurs during operation 408 varies depending on the voltage and duration of the voltage. When a high voltage resulting in a high current is applied for a short period of time, the embedded resistor may experience intrinsic breakdown. In this case, the voltage may be applied only for short durations, such as on the order of 10⁻⁸ seconds. In this situation, the dielectric strength of the embedded resistor increases very rapidly to the intrinsic electric strength. The intrinsic breakdown depends upon the presence of free electrons, which are capable of migration through the lattice of the embedded resistor. For example, small numbers of conduction electrons may present, with some structural imperfections and small amounts of impurities. The impurity atoms or molecules act as traps for the conduction electrons up to a certain level of the electric field and temperature used during operation 408. When these levels are exceeded, additional electrons and trapped are released and participate in the conduction process.

The intrinsic breakdown may be further characterized as an electronic breakdown or an avalanche breakdown. The electronic breakdown assumes the initial density of conduction electrons to be large, such that many electron to electron collisions can occur. When an electric field is applied, the electrons gain energy and cross the gap from the valence band to the conduction band. As the process continues, more and more electrons migrate to the conduction band, eventually leading to the breakdown. During the avalanche breakdown, conduction electrons gain sufficient energy above a certain critical electric field and cause release of electrons from the lattice by collisions. When the energy gained by electrons exceeds their ionization potential, additional electrons are released due to collisions. This process repeats itself.

Electro-mechanical breakdown occurs roughly within the same time frame as the intrinsic breakdown. Failure occurs due to electrostatic compressive forces, which can exceed the mechanical compressive strength. After a longer time frame, a thermal breakdown may occur. Specifically, when an electric field is applied to the embedded resistor, the conduction current may start flowing though the resistor. This initial current heats up the resistor and causes a rise in the temperature. Other types of breakdown include electrochemical breakdown, treeing and tracking, and internal discharges.

During operation 408, a current may pass through the stack that includes the variable resistance layer in addition to the embedded resistor. In some embodiments, the resistive state of the variable resistance layer remains the same during operation 408. Alternatively, the resistive state of the variable resistance layer may change during operation 408. For example, the first current reduces the resistance of the resistance of the variable resistance. In this case, prior to operation 408, the variable resistance layer may have not undergone the forming process to create its first conductive path (as, e.g., described above with reference to FIGS. 1A and 1B) or the variable resistance layer may be present in its high resistive state. In some embodiments, operation 408 also creates an initial filament in the variable resistance layer or switches the variable resistance layer from its high resistive state to its low resistive state.

In some embodiments, passing the first current involves applying a voltage of between 2 Volts and 12 Volts to the stack. It should be noted that the stack includes both the embedded resistor and the variable resistance layer during application of this voltage. The voltage is sufficient to cause the electrical breakdown in the embedded resistor. In some embodiments, the voltage may be applied for between about 10 nanoseconds and 10 microseconds. The voltage may be applied as a set of pulses ramping from a low voltage to a high voltage with the duration of each pulse between about 10 nanoseconds and 10 microseconds. For example, the voltage may increase from 1V to 10V with 0.2V increments and the duration of each pulse being about 1 microsecond. The definition of breakdown is the moment when the current increases significantly (e.g., by more than 5 times). The voltage at which the breakdown occurs is defined as the breakdown voltage.

Operation 408 is typically performed during fabrication of the ReRAM cell, for example, when the second signal line become available to apply a voltage to the cell. The breakdown of the embedded resistor should be also distinguished from changes in resistive states of the variable resistance layer. The variable resistance layer changes its resistance in a reversible manner as described above with reference to FIGS. 2A and 2B. To the contrary, the breakdown of the embedded resistor is irreversible. In other words, once the resistance of the embedded resistor decreases during breakdown, the resistance does not increase during subsequent operation. Furthermore, the controlled breakdown during operation 408 helps to prevent uncontrolled breakdowns during operation of the ReRAM cell by stabilizing the resistance of the embedded resistance.

In some embodiments, the resistance of the embedded resistor drops by a factor of between about 10 and 1000 during operation 408 or, more specifically, by a factor of between about 100 and 1000. The ratio of the resistance of the variable resistance layer to the resistance of the embedded resistor may be between about 0.25 and 4 after operation 408 or, more specifically, between about 0.5 and 2, such as about 1. In some embodiments, the resistivity the embedded resistor is between 0.1 Ohm-cm and 5 Ohm-cm after operation 408.

Method 400 may proceed with passing a second current through a stack including the embedded resistor and the variable resistance layer during operation 410. The second current changes the resistance of the variable resistance layer, while the resistance of the embedded resistor remains substantially the same while passing the second current. The second current may be a set current or a reset current as further described above with reference to FIGS. 2A and 2B. In some embodiments, the first current and the second current are passed in the same direction through the stack. This current may reduce the resistance of the variable resistance layer.

After operation 410, method 400 may involve passing a third current through the stack during operation 412. The third current may increase the resistance of the variable resistance layer, if the variable resistance layer was in its low resistive state, or decrease the resistance of the variable resistance layer, if the variable resistance layer was in its high resistive state. In either case, the resistance of the embedded resistor remains substantially the same while passing the third current. The second current and the third current may be passed in opposite directions through the stack.

### Memory Array Examples

A brief description of memory arrays will now be described with reference to FIGS. 5A and 5B to provide better understanding to various aspects of thermally isolating structures provided adjacent to ReRAM cells and, in some examples, surrounding the ReRAM cells. ReRAM cells described above may be used in memory devices or larger integrated circuits (IC) that may take a form of arrays. FIG. 5A illustrates a memory array 500 including nine ReRAM cells 502, in accordance with some embodiments. In general, any number of ReRAM cells may be arranged into one array. Connections to each ReRAM cell 502 are provided by signal lines 504 and 506, which may be arranged orthogonally to each other. ReRAM cells 502 are positioned at crossings of signal lines 504 and 506 that typically define boundaries of each ReRAM cell in array 500.

Signal lines 504 and 506 are sometimes referred to as word lines and bit lines. These lines are used to read and write data into each ReRAM cell 502 of array 500 by individually connecting ReRAM cells to read and write controllers. Individual ReRAM cells 502 or groups of ReRAM cells 502 can be addressed by using appropriate sets of signal lines 504 and 506. Each ReRAM cell 502 typically includes multiple layers, such as first and second electrodes, variable resistance layer, embedded resistors, embedded current steering elements, and the like, some of which are further described elsewhere in this document. In some embodiments, a ReRAM cell includes multiple variable resistance layers provided in between a crossing pair of signal lines 504 and 506.

As stated above, various read and write controllers may be used to control operations of ReRAM cells 502. A suitable controller is connected to ReRAM cells 502 by signal lines 504 and 506 and may be a part of the same memory device and circuitry. In some embodiments, a read and write controller is a separate memory device capable of controlling multiple memory devices each one containing an array of ReRAM cells. Any suitable read and write controller and array layout scheme may be used to construct a memory device from multiple ReRAM cells. In some embodiments, other electrical components may be associated with the overall array 500 or each ReRAM cell 502. For example, to avoid the parasitic-path-problem, i.e., signal bypasses by ReRAM cells in their low resistance state (LRS), serial elements with a particular non-linearity must be added at each node or, more specifically, into each element. Depending on the switching scheme of the ReRAM cell, these elements can be diodes or varistor-type elements with a specific degree of non-linearity. In the same other embodiments, an array is organized as an active matrix, in which a transistor is positioned at each node or, more specifically, embedded into each cell to decouple the cell if it is not addressed. This approach significantly reduces crosstalk in the matrix of the memory device.

In some embodiments, a memory device may include multiple array layers as, for example, illustrated in FIG. 5B. In this example, five sets of signal lines 514a-b and 516a-c are shared by four ReRAM arrays 512a-c. As with the previous example, each ReRAM array is supported by two sets of signal lines, e.g., array 512a is supported by 514a and 516a. However, middle signal lines 514a-b and 516b, each is shared by two sets ReRAM arrays. For example, signal line set 514a provides connections to arrays 512a and 512b. First and second sets of signal lines 516a and 516c are only used for making electrical connections to one array. This 3-D arrangement of the memory device should be distinguished from various 3-D arrangements in each individual ReRAM cell.

### CONCLUSION

Although the foregoing examples have been described in some detail for purposes of clarity of understanding, the invention is not limited to the details provided. There are many alternative ways of implementing the invention. The disclosed examples are illustrative and not restrictive.

What is claimed:

1. A resistive random access memory (ReRAM) cell comprising:
a first signal line;
a second signal line;
a variable resistance layer disposed between the first signal line and the second signal line; and
a resistor disposed between the first signal line and the second signal line,
wherein the resistor comprises one of a metal silicon nitride, a metal aluminum nitride, or a metal boron nitride,
wherein the resistor is connected in series with the variable resistance layer between the first signal line and the second signal line; and
wherein the resistor is broken down by an applied voltage between about 2V and 12V.

2. The ReRAM cell of claim 1, wherein the resistor comprises one of tantalum silicon nitride, tantalum aluminum nitride, tantalum boron nitride, titanium silicon nitride, titanium aluminum nitride, titanium boron nitride, tungsten silicon nitride, tungsten aluminum nitride, tungsten boron nitride, molybdenum silicon nitride, molybdenum aluminum nitride, or molybdenum boron nitride.

3. The ReRAM cell of claim 1, wherein the resistor comprises tantalum silicon nitride.

4. The ReRAM cell of claim 3, wherein an atomic ratio of tantalum to silicon in the resistor is between 2 and 20.

5. The ReRAM cell of claim 3, wherein the variable resistance layer comprises hafnium oxide.

6. The ReRAM cell of claim 1, wherein a concentration of nitrogen in the resistor is between 20% atomic and 60% atomic.

7. The ReRAM cell of claim 1, wherein the ReRAM cell further comprises an interface layer disposed between the variable resistance layer and the resistor, wherein the interface layer comprises a metal.

8. The ReRAM cell of claim 1, wherein the resistor has a thickness of between about 5 nanometers and 50 nanometers.

9. A method of fabricating a resistive random access memory (ReRAM) cell, the method comprising:
providing a substrate;
forming a resistor on the substrate,
wherein the resistor comprises one of a metal silicon nitride, a metal aluminum nitride, or a metal boron nitride;
forming a variable resistance layer on the resistor to form a stack in which the variable resistance layer and the resistor are connected in series; and
passing a first current through the stack,
wherein the first current causes an electrical breakdown in the resistor and reduces a resistance of the resistor.

10. The method of claim 9, wherein passing the first current changes a resistance of the variable resistance layer.

11. The method of claim 10, wherein passing the first current reduces a resistance of the variable resistance layer.

12. The method of claim 9, further comprising passing a second current through the stack, wherein the second current changes a resistance of the variable resistance layer while leaving the resistance of the resistor substantially unchanged.

13. The method of claim 12, wherein the first current and the second current are passed in a same direction through the stack.

14. The method of claim 12, wherein the second current reduces the resistance of the variable resistance layer.

15. The method of claim 14, further comprising passing a third current through the stack, wherein the third current increases the resistance of the variable resistance layer while leaving the resistance of the resistor substantially unchanged.

16. The method of claim 9, wherein passing the first current comprises applying a voltage of between 2 Volts and 12 Volts to the stack.

17. The method of claim 9, wherein, after passing the first current, a ratio of a resistance of the variable resistance layer and the resistance of the resistor is between about 0.25 and 4.

18. The method of claim 9, wherein a resistivity the resistor is between 0.1 Ohm-cm and 5 Ohm-cm after passing the first current.

19. The method of claim 9, wherein the resistance of the resistor is reduced by a factor of more than 100 by the first current.

20. A method comprising:
providing a resistive random access memory (ReRAM) cell,
wherein the ReRAM cell comprises a variable resistance layer and a resistor,
wherein the variable resistance layer comprises hafnium oxide,
wherein the resistor comprises tantalum silicon nitride of a thickness between 5 nanometers and 50 nanometers, and
wherein the variable resistance layer and the resistor are connected in series;
passing a breakdown current through the variable resistance layer and the resistor,
wherein the breakdown current reduces a resistance of the variable resistance layer and reduces a resistance of the resistor; and
after passing the breakdown current, passing a switching current through the variable resistance layer and the resistor,
wherein the switching current changes the resistance of the variable resistance layer while the resistance of the resistor remains substantially unchanged.
